(19) United States
(12) Patent Application Publication
(10) Pub. No.: US 2025/0267855 A1
(43) Pub. Date: Aug. 21, 2025

(54) SEMICONDUCTOR DEVICE AND METHOD FOR FABRICATING THE SAME

(71) Applicant: SK hynix Inc., Gyeonggi-do (KR)

(72) Inventors: Na Hye WON, Gyeonggi-do (KR); Sung Soo KIM, Gyeonggi-do (KR)

(21) Appl. No.: 18/898,684

(22) Filed: Sep. 27, 2024

(30) Foreign Application Priority Data
Feb. 21, 2024 (KR) 10-2024-0024916

(51) Int. Cl. H10B 12/00

(52) U.S. Cl. CPC H10B 12/485; H10B 12/09; H10B 12/34; H10B 12/482; H10B 12/50

(57) ABSTRACT

A semiconductor device includes: a gate capping layer formed over a substrate and including a contact hole; a contact suitable for gap-filling the contact hole and including a protrusion portion whose top surface is disposed at a higher level than a top surface of the gate capping layer; and a first barrier suitable for covering top and side surfaces of the contact exposed through an upper portion of the gate capping layer; and a conductive line over the first barrier.

### CROSS-REFERENCE TO RELATED APPLICATIONS

The present application claims priority under 35 U.S.C 119(a) to Korean Patent Application No. 10-2024-0024916, filed on Feb. 21, 2024, which is incorporated herein by reference in its entirety.

### BACKGROUND

### 1. Field

Various embodiments of the present invention relate to a semiconductor device and a method for fabricating the same, and more particularly, to a semiconductor device including a conductive structure, and a method for fabricating the semiconductor device.

### 2. Description of the Related Art

Recently, as semiconductor devices become more highly integrated, process difficulty may be increased and process margins may be decreased continuously. In particular, as the line widths of conductive structures become narrower, overlay margin defects between the conductive structures and contacts connecting the conductive structures to a substrate may occur. As a result, resistance may increase due to undesired etching of the contact or a short circuit may occur between the contact and an upper layer. Hence, new structures and techniques are needed to overcome these issues.

### SUMMARY

Various embodiments of the present invention are directed to an improved semiconductor device structure that prevents contact loss and an increase in resistance resulting from the contact loss or a short circuit between upper layers of the semiconductor device. Various embodiments of the present invention are also directed to a method for fabricating the semiconductor device.

In accordance with an embodiment of the present invention, a semiconductor device includes a gate capping layer formed over a substrate and including a contact hole; a contact suitable for gap-filling the contact hole and including a protrusion portion whose top surface is disposed at a higher level than a top surface of the gate capping layer; and a first barrier suitable for covering top and side surfaces of the contact exposed through an upper portion of the gate capping layer; and a conductive line over the first barrier.

In accordance with another embodiment of the present invention, a semiconductor device includes a substrate including a first region and a second region; a gate capping layer formed over the first region of the substrate and including a contact hole; a contact suitable for gap-filling the contact hole and including a protrusion portion whose top surface is disposed at a higher level than a top surface of the gate capping layer; a first barrier suitable for covering top and side surfaces of the contact exposed through an upper portion of the gate capping layer; a conductive line formed over the first barrier to be aligned with a side surface of the first barrier; and a peripheral gate structure formed over the second region of the substrate.

In accordance with another embodiment of the present invention, a method for fabricating a semiconductor device includes forming a gate capping layer and a sacrificial layer including a contact hole over a substrate; forming a contact spacer that covers an inner surface of the contact hole; forming a contact to gap-fill the contact hole; forming a contact protrusion portion whose top surface is disposed at a higher level than a top surface of the gate capping layer by removing the sacrificial layer; and forming a conductive structure including a first barrier that covers the contact protrusion portion.

In accordance with another embodiment of the present invention, a method for fabricating a semiconductor device includes: providing a substrate including a first region and a second region; forming a gate capping layer including a contact hole over the substrate in the first region; forming a contact gap-filling the contact hole and including a protrusion portion whose top surface is disposed at a higher level than a top surface of the gate capping layer; forming a conductive structure over the substrate in the first region, the conductive structure including a first barrier and a conductive line over the first barrier, the first barrier covering top and side surfaces of the contact exposed through an upper portion of the gate capping layer, and the conductive line aligned with a side of the first barrier; forming a peripheral gate structure over the substrate in the second region.

In accordance with another embodiment of the present invention, a semiconductor device includes a gate capping layer formed over a substrate, a contact formed partially within the gate capping layer, the contact including a protrusion portion extending above a top surface of the gate capping layer and a lower portion extending below the top surface of the gate capping layer; at least one barrier layer covering a top surface and a side surface of the protrusion portion of the contact; and a conductive line disposed over the at least one barrier layer. These and other features and advantages of the embodiments of the present invention will become apparent from the following drawings and detailed description.

### BRIEF DESCRIPTION OF THE DRAWINGS

FIG. 1 is a plan view illustrating a semiconductor device in accordance with an embodiment of the present invention.

FIG. 2 is a cross-sectional view illustrating a semiconductor device in accordance with the embodiment of the present invention.

FIGS. 3A to 3K are cross-sectional views illustrating a method for fabricating a semiconductor device in accordance with an embodiment of the present invention.

FIG. 4 is a plan view illustrating a semiconductor device in accordance with an embodiment of the present invention.

FIG. 5 is a cross-sectional view illustrating a semiconductor device in accordance with the embodiment of the present invention.

FIGS. 6A to 60 are cross-sectional views illustrating a method for fabricating a semiconductor device in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present invention.

The drawings are not necessarily to scale and in some instances, proportions may have been exaggerated to clearly illustrate features of the embodiments. When a first layer is referred to as being “on” a second layer or “on” a substrate, it may not only refer to a case where the first layer is formed directly on the second layer or the substrate but also to a case where a third layer may exist between the first layer and the second layer or the substrate.

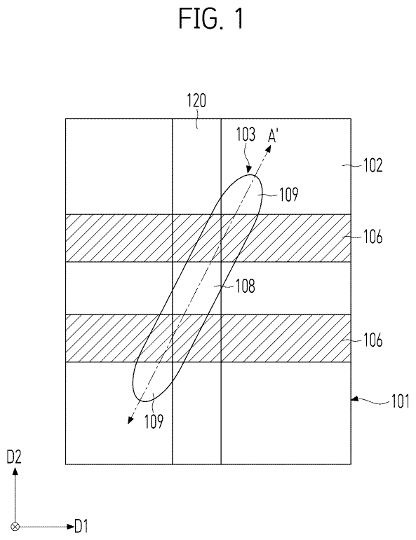

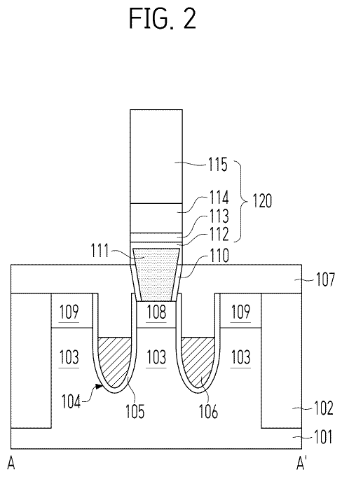

FIG. 1 is a plan view illustrating a semiconductor device in accordance with an embodiment of the present invention. FIG. 2 is a cross-sectional view of FIG. 1 illustrating the semiconductor device in accordance with the embodiment of the present invention. Here, an A-A′ direction may be the same as the long axis direction of an active region. In FIGS. 1 and 2, the same reference numerals may indicate the same region.

Referring to FIGS. 1 and 2, a semiconductor device may include a plurality of memory cells. The memory cells may include conductive structures that are disposed at different levels. For example, each memory cell may include a cell transistor including a buried gate 106, a bit line 120, and a memory element.

An isolation layer 102 defining an active region 103 may be formed in a substrate 101. A plurality of active regions 103 may be defined by the isolation layer 102. Each active region 103 may have a bar shape having a major axis and a minor axis. The active regions 103 may be arranged spaced apart from each other at regular intervals. Each active region 103 may be spaced apart from each other in a first direction D1 and a second direction D2 which is perpendicular to the first direction D1. The active regions 103 may be tilted diagonally.

The substrate 101 may include a material containing silicon. The substrate 101 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include other semiconductor materials such as germanium. The substrate 101 may include a group-III/V semiconductor substrate, for example, a compound semiconductor substrate, such as GaAs. The substrate 101 may include a Silicon-On-Insulator (SOI) substrate.

A line-shaped buried gate 106 extending in the first direction D1 may be formed over the substrate 101. The buried gate 106 may be disposed at a lower level than the top surface of the substrate 101. The buried gate 106 may gap-fill a portion of gate trench 104. The buried gate 106 may form a buried gate structure along with a gate dielectric layer 105 interposed between the gate trench 104 and the buried gate 106, and a gate capping layer 107 that fills the remaining portion of the gate trench 104 over the buried gate 106. The buried gate structure may also be referred to as a ‘buried word line’.

To be specific, a line-shaped gate trench 104 may be formed over the substrate 101 to intersect with the active regions 103 and the isolation layer 102 in the first direction D1. The gate trench 104 may be formed in the substrate 101 to a predetermined depth. The bottom surface of the gate trench 104 may be disposed at a higher level than the bottom surface of the isolation layer 102. The gate trench 104 may have a shallower depth than the isolation layer 102. According to another embodiment of the present invention, the isolation layer 102 in a direction that the gate trench 104 extends may be etched to a predetermined depth to form a fin in the active region 103.

A gate dielectric layer 105 may be formed on the surface of the gate trench 104. A buried gate 106 may be formed over the gate dielectric layer 105 to partially fill the gate trench 104. The buried gate 106 may also be referred to as a ‘buried conductive layer 106’. The buried gate 106 may also be referred to as a ‘buried gate electrode 106’. A gate capping layer (i.e., a sealing layer) 107 may be formed over the buried gate 106 to fill the remaining portion of the gate trench 104. The top surface of the gate capping layer 107 may be disposed at a higher level than the top surface of the substrate 101. The gate capping layer 107 may cover the upper portion of the buried gate 106 and also the upper portion of the substrate 101. The buried gate 106 may include at least one low-resistance metal material arranged in one or more layers. For example, the buried gate 106 may be formed by sequentially stacking titanium nitride and tungsten. According to another embodiment of the present invention, the buried gate 106 may be formed of titanium nitride (TiN) only.

First and second impurity regions 108 and 109 may be formed in the substrate 101. The first and second impurity regions 108 and 109 may be referred to as ‘first and second doped regions 108 and 109’. The first and second impurity regions 108 and 109 may be referred to as ‘first and second source/drain regions 108 and 109’. The first and second impurity regions 108 and 109 may be spaced apart from each other by the gate trench 104. Accordingly, the buried gate 106 and the first and second impurity regions 108 and 109 may form a cell transistor. The cell transistor may be formed to have a buried gate structure and improved characteristics, and in particular a reduced short channel effect or effects.

A contact 111 may be formed over the substrate 101 overlapping with the first impurity region 108. The contact 111 may be coupled to the first impurity region 108. The contact 111 may protrude toward the upper portion of the gate capping layer 107. The top surface of the contact 111 may be disposed at a higher level than the top surface of the gate capping layer 107. The top surface of the contact 111 may be disposed at a higher level than the surface of the substrate 101. The bottom surface of the contact 111 may be disposed at a lower level than the top surface of the substrate 101. The bottom surface of the contact 111 may be lower than the top surface of the active region 103 including the first and second impurity regions 108 and 109. The contact 111 may have a line width which is smaller than the diameter of a contact hole. A contact spacer 110 may be disposed between the contact 111 and the contact hole. The contact spacer 110 may include a dielectric material. For example, the contact spacer 110 may include silicon nitride. The contact 111 may include a conductive material. For example, the contact 111 may include polysilicon. Also, the contact 111 may include doped polysilicon. In particular, according to this embodiment of the present invention, the contact 111 may include polysilicon that is doped with phosphorus (P). According to another embodiment of the present invention, the contact 111 may include a conductive material. The contact 111 may be referred to as a ‘bit line contact 111’.

A conductive structure 120 may be formed over the contact 111. The conductive structure 120 may be referred to as a ‘bit line structure 120’. The conductive structure 120 may include a stacked structure of a first barrier layer 112, a second barrier layer 113, a conductive line 114, and a conductive line hard mask 115. The conductive line 114 may be referred to as a ‘bit line 114’. According to another embodiment of the present invention, the stacked structure of the first and second barrier layers 112 and 113 and the conductive line 114 may be referred to as ‘bit lines 112, 113, and 114.’ The conductive line hard mask 115 may be referred to as a ‘bit line hard mask 115’.

The conductive structure 120 may be of a line type extending in the second direction D2. The first and second barrier layers 112 and 113, the conductive line 114, and the conductive line hard mask 115 may be of a line type extending in the second direction D2. The side surfaces of the first and second barrier layers 112 and 113, the conductive line 114, and the conductive line hard mask 115 may be aligned in a direction perpendicular to the surface of the substrate 101. The conductive structures 120 may be arranged spaced apart from each other in the first direction D1.

A portion of the conductive structure 120 may be coupled to the contact 111. In particular, according to this embodiment of the present invention, the first barrier layer 112 may cover a portion of the contact 111 that protrudes above the top surface of the gate capping layer 107 and which is referred to as the protrusion portion of the contact 111. The first barrier layer 112 may cover the protrusion portion of the contact 111. To be specific, the first barrier layer 112 may cover the top and side surfaces of the protrusion portion of the contact 111 which is disposed at a higher level than the top surface of the gate capping layer 107. The side surface of the contact 111 disposed at a lower level than the top surface of the gate capping layer 107 may be covered by the contact spacer 110. A first barrier layer 112 may be formed over the contact spacer 110. Accordingly, the side surface of the contact 111 may be covered by a stacked structure of the contact spacer 110 and the first barrier layer 112.

The first barrier layer 112 may include a material having an etch selectivity with respect to the contact 111 and the gate capping layer 107. The first barrier layer 112 may include a conductive material. For example, the first barrier layer 112 may include a stacked structure of titanium (Ti) and tungsten nitride (WN), but the embodiment is not limited thereto.

The second barrier layer 113 may be formed over the first barrier layer 112. The second barrier layer 113 may include a conductive material. For example, the second barrier layer 113 may include tungsten silicide nitride (WSiN), but the embodiment is not limited thereto.

The conductive line 114 may include a metal material. For example, the conductive line 112 may include tungsten (W), but the embodiment is not limited thereto.

The conductive line hard mask 115 may include a dielectric material. For example, the conductive line hard mask 115 may include silicon nitride, but the embodiment is not limited thereto.

As described above, according to this embodiment of the present invention, the contact area between the contact 111 and the conductive structure 120 may be increased by applying a protrusion portion disposed at a higher level than the top surface of the gate capping layer 107 to the top surface of the contact 111 and covering the protrusion portion of the contact 111 with the first barrier layer 112. Also, as the contact area is increased, the contact resistance between the contact 111 and the conductive structure 120 may be decreased.

Furthermore, the first barrier layer 112 may cover the protrusion of the contact 111, thereby preventing a profile change due to a difference in the etch ratio between the contact 111 and the first barrier layer 112. As a comparative example, when the general contact process and the conductive structure process are performed sequentially, a polysilicon layer may be applied to form a loss compensation layer between the first barrier layer 112 and the contact 111. However, it is noted that the present embodiment can prevent profile changes without further deposition of the polysilicon layer.

Also, an overlay margin between the contact 111 and the conductive structure 120 may be secured.

Also, even though misalignment occurs between the contact 111 and the conductive structure 120, the loss of the contact 111 may be minimized based on the etch selectivity between the first barrier layer 112, which is the lowermost layer of the conductive structure 120, and the contact 111. Therefore, there is an advantageous effect of stabilizing the formation of spacers of the conductive structure 120 that is formed by a subsequent process. Also, as the formation of spacers is stabilized, there is an advantageous effect of preventing a short circuit between the contact 111 and the upper layer.

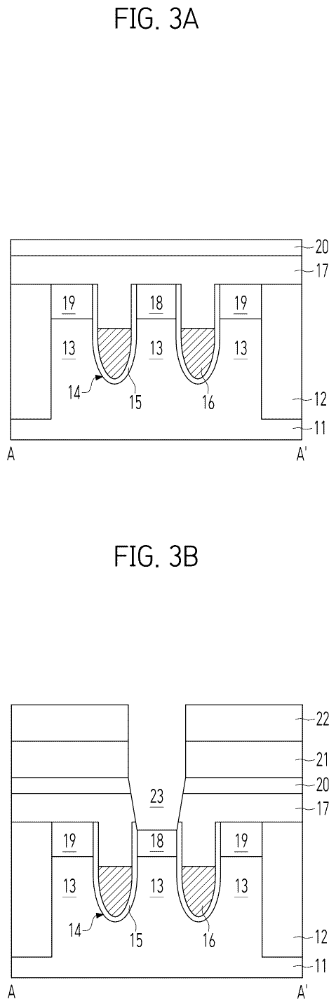

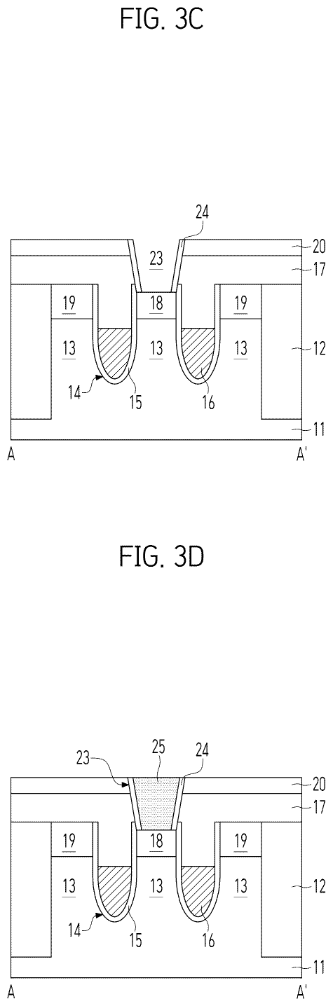

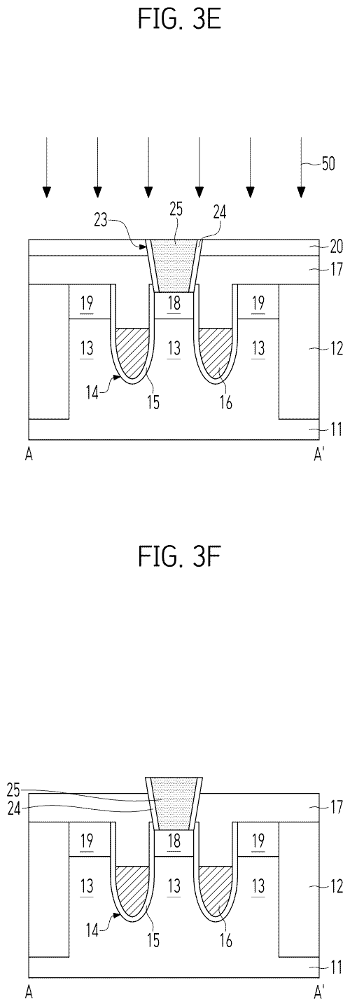

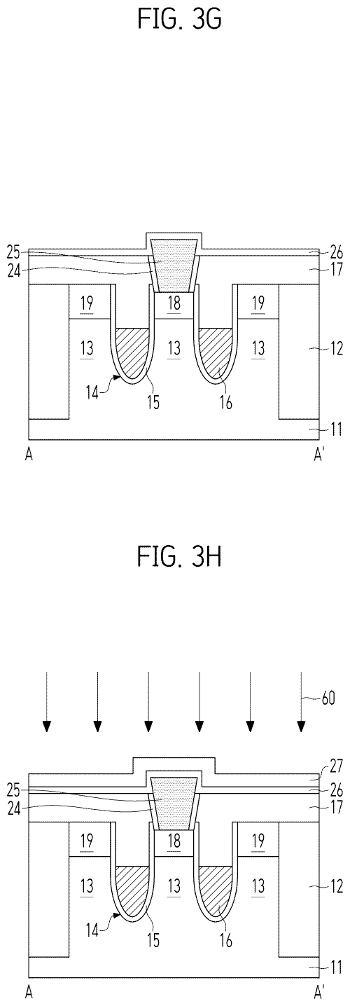

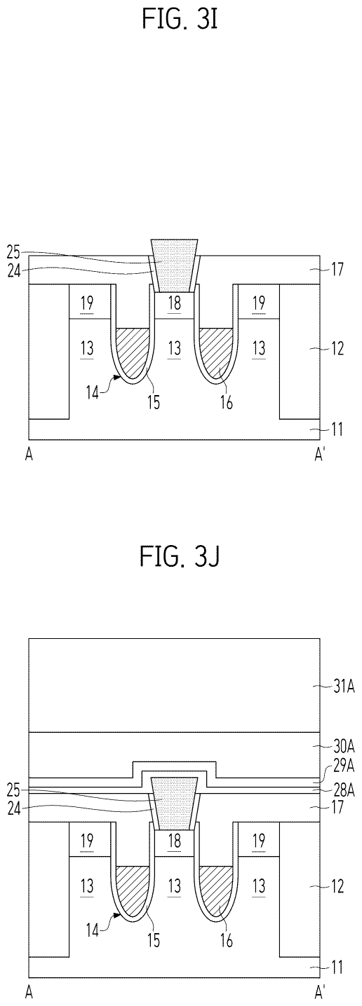

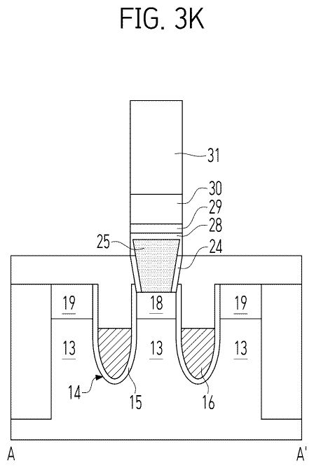

FIGS. 3A to 3K are cross-sectional views illustrating a method for fabricating a semiconductor device in accordance with an embodiment of the present invention. FIGS. 3A to 3K illustrate a method for fabricating the semiconductor device illustrated in FIG. 2.

Referring to FIG. 3A, an isolation layer 12 may be formed over the substrate 11. The active region 13 may be defined by the isolation layer 12. Referring to FIG. 1, each active region 13 may have a long bar shape having a major axis and a minor axis.

The isolation layer 12 may be formed by a Shallow Trench Isolation (STI) process. The STI process may be performed as follows. The substrate 11 may be etched to form an isolation trench (whose reference numeral is omitted) and the isolation trench may then be filled with a dielectric material to form the isolation layer 12. The isolation layer 12 may include silicon oxide, silicon nitride, or a combination thereof. A Chemical Vapor Deposition (CVD) process or another deposition process may be used to fill the isolation trench with a dielectric material. A planarization process such as Chemical Mechanical Polishing (CMP) may be additionally used.

Subsequently, a gate trench 14 may be formed in the substrate 11. The gate trench 14 may have a shape of a line crossing the isolation layer 12 and the active region 13. The bottom surface of the gate trench 14 may have a curvature. The bottom surface of the gate trench 14 may be disposed at a higher level than the bottom surface of the isolation layer 12. According to another embodiment of the present invention, the gate trench 14 may include a fin whose bottom surface in the isolation layer 12 is disposed at a lower level than the bottom surface in the active region 11.

Subsequently, a gate dielectric layer 15 that conformally covers the surface of the gate trench 14 may be formed. The gate dielectric layer 15 may include a dielectric material. For example, the gate dielectric layer 15 may include silicon oxide. The gate dielectric layer 15 may be formed through a deposition process or a selective oxidation process, but the embodiment is not limited thereto.

Subsequently, a buried gate 16 may be formed over the gate dielectric layer 15. Referring to FIG. 1, the buried gate 16 may have a line shape extending in the first direction D1. The buried gate 16 may gap-fill a portion of the gate trench 14. The top surface of the buried gate 16 may be disposed at a lower level than the bottom surfaces of the first and second impurity regions 18 and 19. A channel may be formed along the surface of the gate trench 14 which is gap-filled with the buried gate 16. The buried gate 16 may include a conductive material. The buried gate 16 may include a low-resistance material. The buried gate 16 may include a single structure. According to another embodiment of the present invention, the buried gate 16 may include a stacked structure. For example, the buried gate 16 may include a single structure of tungsten or titanium nitride. According to another embodiment of the present invention, the buried gate 16 may include a stacked structure of titanium nitride and tungsten. According to another embodiment of the present invention, the buried gate 16 may include a stacked structure of tungsten nitride and tungsten. According to another embodiment of the present invention, the buried gate 16 may include a stacked structure of a lower electrode and an upper electrode, and a high work function material may be interposed between the lower electrode and the gate dielectric layer 15, and a low work function material may be interposed between the upper electrode and the gate dielectric layer 15. This embodiment of the present invention is not limited to this, and all known buried gate structures may be applied.

Subsequently, a gate capping layer 17 may be formed over the buried gate 16 to gap-fill the remaining portion of the trench 14. The gate capping layer 17 may be formed by a series of processes of depositing a dielectric material to gap-fill the remaining portion of the trench 14 over the buried gate 16 and performing a planarization process. For example, the planarization process may include a chemical mechanical polishing (CMP) process.

The gate capping layer 17 may cover the upper portion of the buried gate 16 and the upper portion of the substrate 11. The top surface of the gate capping layer 17 may be disposed at a higher level than the top surface of the substrate 11. The gate capping layer 17 may include a dielectric material. For example, the gate capping layer 17 may include silicon nitride. According to another embodiment of the present invention, the gate capping layer 17 may include a stacked structure. Herein, the stacked structure may include the gate capping layer 17 gap-filling the gate trench 14 and the gate capping layer 17 formed over the substrate 11. Herein, the gate capping layer 17 gap-filling the gate trench 14 and the gate capping layer 17 formed over the substrate 11 may include different dielectric materials.

Subsequently, a first impurity region 18 and a second impurity region 19 may be formed over the substrate 11. The first and second impurity regions 18 and 19 may be formed through a doping process such as an implantation process. Hereinafter, the first and second impurity regions 18 and 19 will be referred to as ‘first and second source/drain regions 18 and 19’. The first source/drain region 18 and the second source/drain region 19 may have the same depth. According to another embodiment of the present invention, the first source/drain region 18 may be deeper than the second source/drain region 19. The first source/drain region 18 may be a region to which a bit line contact is to be coupled. The second source/drain region 19 may be a region to which a storage contact is to be coupled.

Subsequently, a sacrificial layer 20 may be formed over the gate capping layer 17. The sacrificial layer 20 may be applied to form a protrusion portion of the contact through a subsequent process. The sacrificial layer 20 may include a dielectric material having an etch selectivity with respect to the gate capping layer 17. For example, the sacrificial layer 20 may include silicon oxide.

Referring to FIG. 3B, a hard mask pattern 21 and a mask pattern 22 may be formed over the sacrificial layer 20.

The hard mask pattern 21 may include a material having an etch selectivity with respect to the gate capping layer 17 and the substrate 11. The hard mask layer 21 may include a stacked structure. Also, the hard mask layer 21 may include a stacked structure of a carbon-based material and an oxide material. For example, the hard mask layer 21 may include a stacked structure of a first Spin-On-Carbon (SOC) and a first silicon oxynitride (SiON).

Subsequently, a mask pattern 22 may be formed over the hard mask pattern 21. The mask pattern 22 may include a stacked structure of a carbon-based material, an anti-reflection layer, and a photosensitive layer. For example, the mask pattern 22 may include a stacked structure of a second spin-on-carbon, a second silicon oxynitride, and a photoresist.

To form the hard mask pattern 21 and the mask pattern 22, first, a first spin-on-carbon and a first silicon oxynitride for a hard mask may be sequentially formed over the sacrificial layer 20, and a second spin-on-carbon and a second silicon oxynitride for etching the hard mask may be sequentially formed over the first silicon oxynitride. Subsequently, after the upper portion of the second silicon oxynitride is coated with the photosensitive layer, a photoresist pattern may be formed by patterning the photosensitive layer through exposure and development processes, and the mask pattern 22 may be formed by sequentially etching the second silicon oxynitride and the second spin-on-carbon with the photoresist pattern. Subsequently, the hard mask pattern 21 may be formed by sequentially etching the first silicon oxynitride and the first spin-on-carbon by using the mask pattern 22.

Subsequently, a contact hole 23 may be formed by sequentially etching the sacrificial layer 20 and the gate capping layer 17 that are exposed by the hard mask pattern 21. The bottom surface of the contact hole 23 may be disposed at a lower level than the top surface of the substrate 11. The top surface of the first source/drain region 18 may be disposed at a lower level than the top surface of the second source/drain region 19. The side surface of the contact hole 23 may have a positive slope meaning that a line width of the upper portion of the contact hole may be wider than the line width of the lower portion of the contact hole. According to another embodiment of the present invention, the side surface of the contact hole 23 may be vertical.

Subsequently, the hard mask pattern 21 and the mask pattern 22 may be removed. According to another embodiment of the present invention, after the hard mask pattern 21 is formed, the mask pattern 22 may be removed, and the sacrificial layer 20 and the gate capping layer 17 may be patterned by using the hard mask pattern 21, and then the hard mask pattern 21 may also be removed.

Referring to FIG. 3C, a contact spacer 24 covering the inner surface of the contact hole 23 may be formed. The contact spacer 24 may be formed by conformally depositing a dielectric material on the profile of the structure including the contact hole 23, and then performing a spacer etching process on the dielectric material so that the dielectric material remains only on the side surface of the contact hole 23. For example, the spacer etching process may include an etch-back process.

The contact spacer 24 may include a dielectric material. For example, the contact spacer 24 may include silicon nitride. The contact spacer 24 may completely cover the inner surface of the contact hole 23. The contact hole 23 and the contact spacer 24 may expose the substrate 11, more specifically, the first source/drain region 18.

Referring to FIG. 3D, a contact 25 may be formed to gap-fill the contact hole 23. The contact 25 may be formed by a series of processes of depositing a conductive material that gap-fills the contact hole 23 and then etching the conductive material targeting to expose the top surface of the sacrificial layer 20. For example, the etching of the conductive material may include an etch-back process or a chemical mechanical polishing (CMP) process. For example, the conductive material may include polysilicon. The top surface of the contact 25 may be disposed at the same level as the top surface of the sacrificial layer 20.

Referring to FIG. 3E, a first contact ion implantation process 50 may be performed for reducing the contact resistance by doping the contact 25 with an impurity. For example, the impurity may include phosphorus (P).

Referring to FIG. 3F, the sacrificial layer 20 (see FIG. 3E) may be removed, for example, by an oxide stripping process. The oxide stripping process may include a dry stripping process or a wet stripping process. For example, the dry stripping process can be performed using carbon tetrafluoride (CF₄) and oxygen (O₂). For example, the wet stripping process can be performed using hydrogen fluoride (HF) or buffered oxide etch (BOE). The gate capping layer 17, the contact spacer 24, and the contact 25 may remain without being lost due to their etch selectivity.

Accordingly, the contact 25 and the contact spacer 24 may protrude toward the upper portion of the gate capping layer 17. The top surface of the contact 25 may be disposed at a higher level than the top surface of the gate capping layer 17. The contact 25 at a level higher than the top surface of the gate capping layer 17 may be referred to as a ‘contact protrusion portion’.

Referring to FIG. 3G, a capping oxide layer 26 covering the top surface of the contact 25 may be formed. The capping oxide layer 26 may be formed by an oxidation process. For example, the oxidation process may be performed as a Rapid Thermal Oxidation (RTO) process. The capping oxide layer 26 may cover the entire surface exposed in FIG. 3F, that is, the top surface of the contact 25, a portion of the contact spacer 24, and the top surface of the gate capping layer 17. To be specific, the top surface of the gate capping layer 17, and a portion of the contact spacer 24 and the top surface of the contact 25 disposed at a higher level than the gate capping layer 17 and protruding may be replaced with the capping oxide layer 26 through an oxidation process.

In another embodiment, the capping oxide layer 26 may be formed through a deposition process.

Referring to FIG. 3H, a sacrificial high dielectric layer 27 may be formed over the capping oxide layer 26. The sacrificial high dielectric layer 27 may be a gate component of a peripheral circuit region and may be removed in a subsequent process.

Subsequently, a second contact ion implantation 60 may be performed. The second contact ion implantation 60 may be performed at a higher energy level than that of the first contact ion implantation 50. The second contact ion implantation 60 may be adjusted to a higher energy level than the energy level of the first contact ion implantation 50 in consideration of the thicknesses of the capping oxide layer 26 and the sacrificial high dielectric layer 27.

The second contact ion implantation 60 may be performed to reduce the contact resistance by doping the contact 25 with an impurity. For example, the impurity may include phosphorus (P).

It is possible to prevent external diffusion of the impurity during a subsequent heat treatment (for example, a heat treatment for activation of an impurity after the gate electrode of the peripheral circuit region is doped with the impurity) by covering the upper portion of the contact 25 with the capping oxide layer 26 during the second contact ion implantation 60. Since the contact 25 includes a high concentration of the impurity, the contact resistance may be reduced.

As a comparative example, when the second contact ion implantation 60 is performed without the capping oxide layer 26, the resistance of the contact 25 may be slightly reduced or may not be reduced at all due to the external diffusion of the impurity during the subsequent heat treatment.

Referring to FIG. 3I, the sacrificial high dielectric layer 27 (see FIG. 3H) and the capping oxide layer 26 (see FIG. 3H) may be removed. The sacrificial high dielectric layer 27 and the capping oxide layer 26 may be removed by a cleaning process. The cleaning process may be performed using an oxide stripping process. The stripping process may include a dry stripping process or a wet stripping process. For example, the dry stripping process can be performed using carbon tetrafluoride (CF₄) and oxygen (O₂). For example, the wet stripping process can be performed using hydrogen fluoride (HF) or buffered oxide etch (BOE). As a result, a portion of the contact 25 may protrude toward the upper portion of the gate capping layer 17. The gate capping layer 17 may expose a contact protrusion portion, that is, the top surface of the contact 25 and a portion of the side surface of the contact 25.

As a portion of the protruding capping spacer 24 (see FIG. 3G) is replaced by the capping oxide layer 26, the top surface of the capping spacer 24 may be disposed at the same level as the top surface of the gate capping layer 17.

Referring to FIG. 3J, a first barrier layer 28A, a second barrier layer 29A, a conductive material layer 30A, and a conductive line hard mask layer 31A may be sequentially formed on the profile of the structure including the contact 25.

The first barrier layer 28A may be conformally lined along the profile of the structure including the contact 25. The first barrier layer 28A may cover the top surface of the contact 25 and a portion of the side surface of the contact 25. The first barrier layer 28A may include a stacked structure. The first barrier layer 28A may include a conductive material. For example, the first barrier layer 28A may include a stacked structure of titanium (Ti) and tungsten nitride (WN).

The second barrier layer 29A may be conformally lined in the upper portion of the first barrier layer 28A. The second barrier layer 29A may include a conductive material. For example, the second barrier layer 29A may include tungsten silicide nitride (WSiN).

The conductive material layer 30A may include a conductive material. For example, the conductive material layer 30A may include tungsten (W). For example, tungsten may be deposited by a physical vapor deposition (PVD) process.

After the conductive material layer 30A is formed, a planarization process may be performed, but the embodiment is not limited to this. For example, the planarization process may include an etch-back process or a Chemical Mechanical Polishing (CMP) process.

The conductive line hard mask layer 31A may protect the conductive material layer 30A and may serve as an etch barrier for etching the conductive material layer 30A, the second barrier layer 29A, and the first barrier layer 28A. The conductive line hard mask layer 31A may include a dielectric material. For example, the conductive line hard mask layer 31A may include silicon nitride.

Referring to FIG. 3K, a conductive structure may be formed. The conductive structure may include a stacked structure of a first barrier 28, a second barrier 29, a conductive line 30, and a conductive line hard mask 31.

According to this embodiment of the present invention, the contact 25 and the conductive structure may overlap with each other in a direction perpendicular to the surface of the substrate 11. The side surfaces of the first barrier 28, the second barrier 29, the conductive line 30, and the conductive line hard mask 31 may be aligned in a direction perpendicular to the top surface of the substrate 11. The line width of the conductive structure may be larger than the line width of the contact 25. Accordingly, the first barrier 28 may cover the top surface of the contact 25 and a portion of the side surface of the contact 25.

As described above, according to this embodiment of the present invention, since the first barrier layer 28 covers not only the top surface of the contact 25 but also a portion of the side surface of the contact 25, the contact area between the contact 25 and the first barrier layer 28 may be increased. Accordingly, stable titanium silicide (TiSix) may be formed.

Also, according to this embodiment of the present invention, even though part of the contact 25 is exposed due to misalignment occurring during an etch process for forming a conductive structure, the loss of the contact 25 may be minimized by forming the first barrier 28 having an etch selectivity with respect to the contact 25 as the lowermost layer of the conductive structure. Therefore, there is an effect of stabilizing the formation of the spacers of the conductive structure that is formed by a subsequent process. Also, as the formation of the spacers is stabilized, there is an effect of preventing a short circuit between the contact 25 and the upper layer.

Subsequently, a process of forming spacers that covers both sides of the conductive structure, a process of forming a contact plug disposed between the neighboring conductive structures and coupled to the second source/drain region 19, and a process of forming a memory element that is disposed over the contact plug and coupled to the substrate 11 through the contact plug may be further performed.

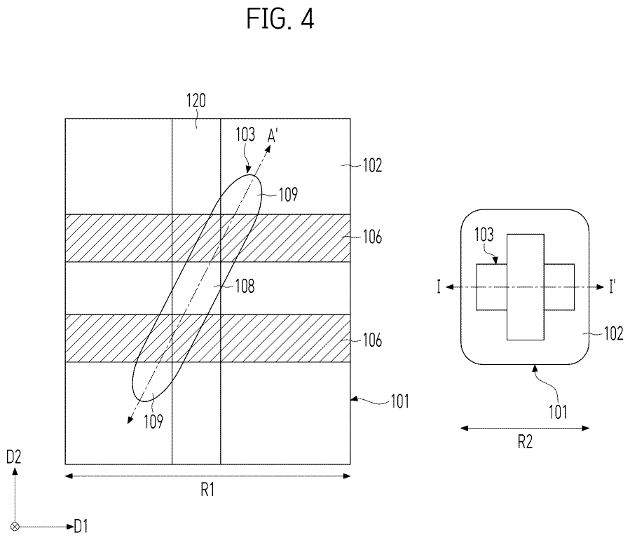

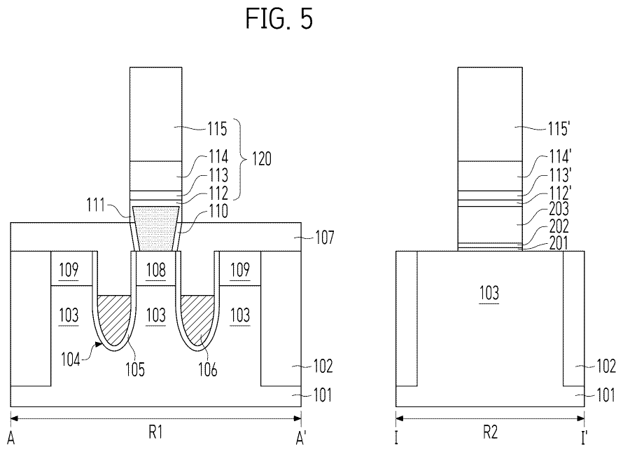

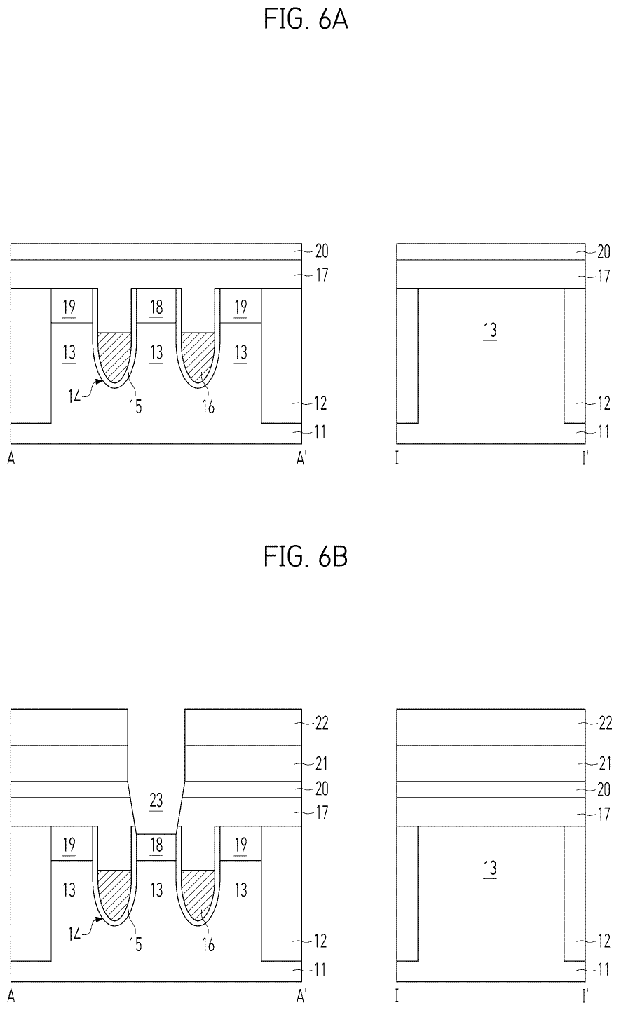

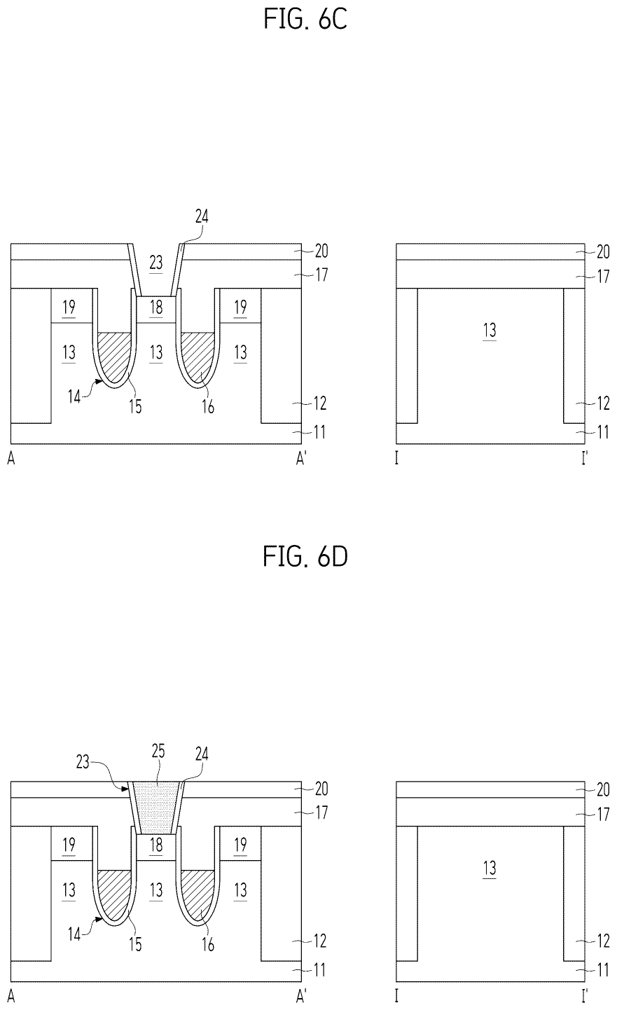

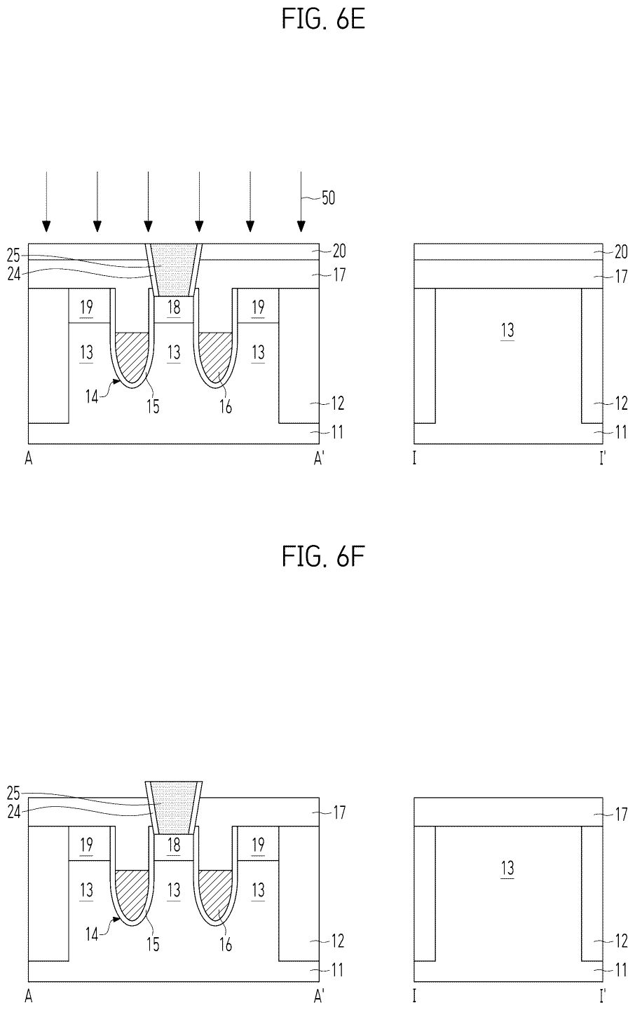

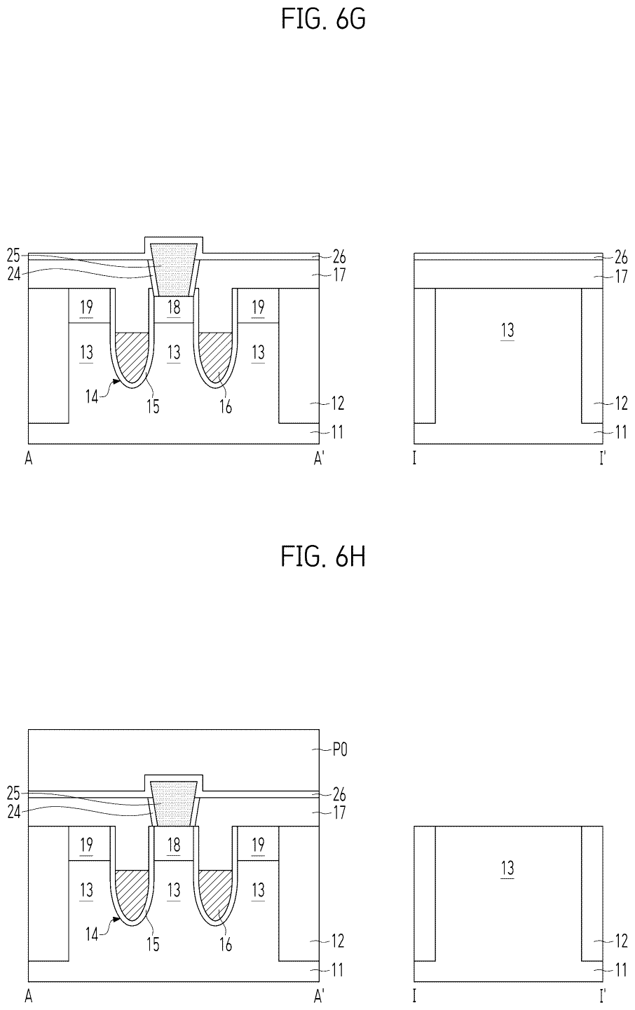

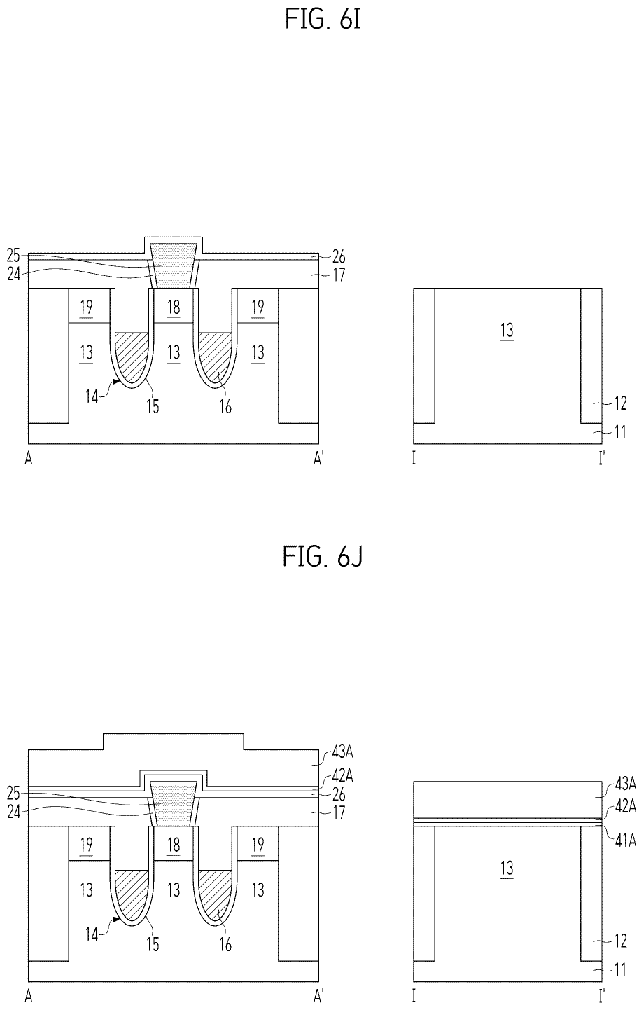

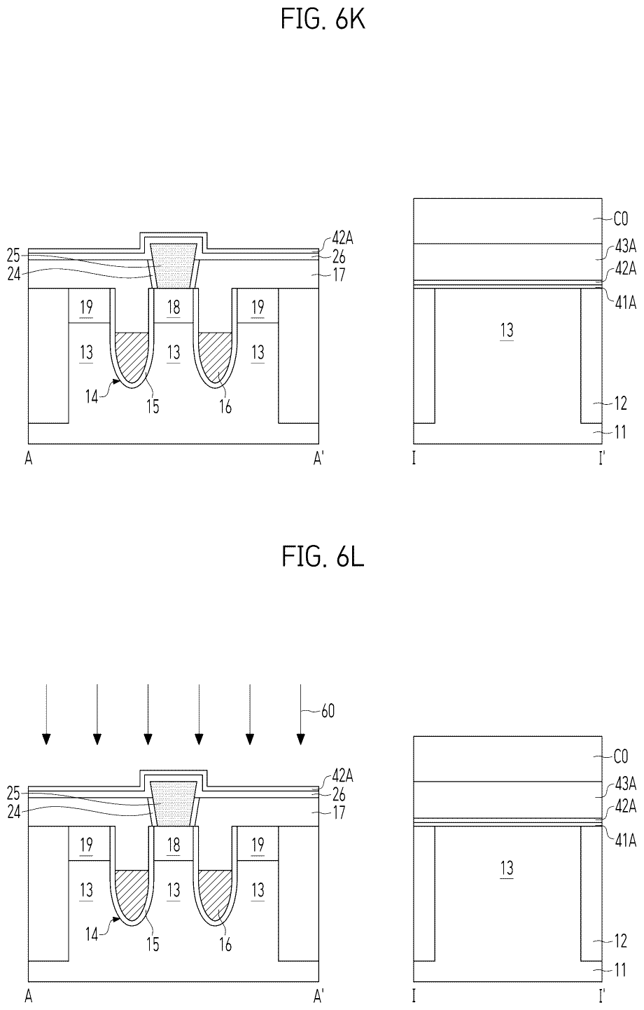

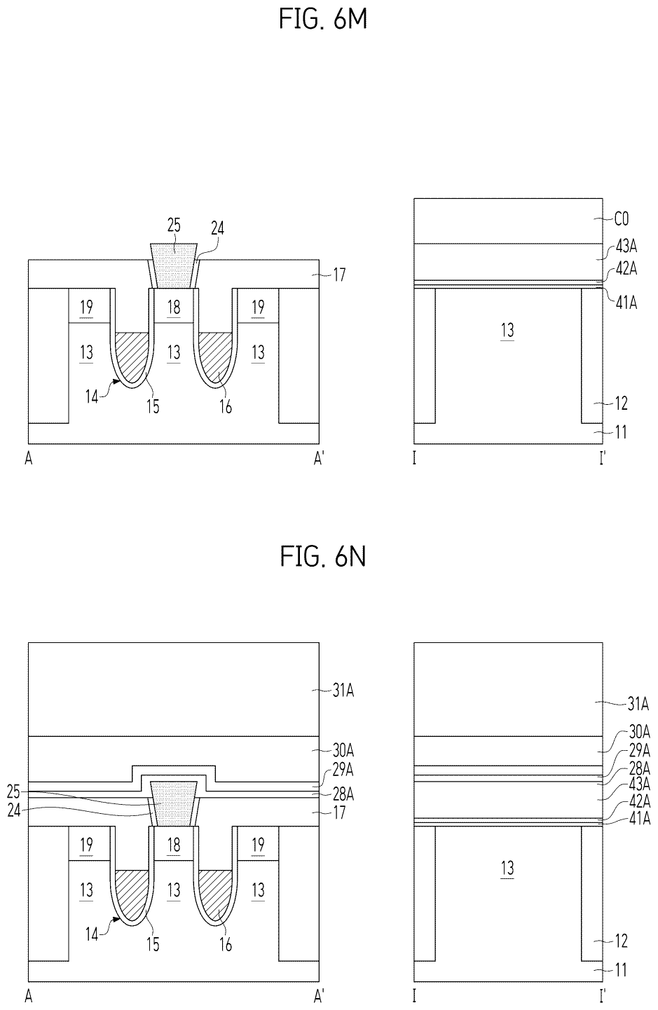

FIG. 4 is a plan view illustrating a semiconductor device in accordance with an embodiment of the present invention. FIG. 5 is a cross-sectional view of the embodiment of FIG. 4. FIGS. 6A to 60 are cross-sectional views illustrating a method for fabricating a semiconductor device in accordance with an embodiment of the present invention.

Referring to FIGS. 4 and 5, the semiconductor device may include a first region R1 and a second region R2. The first region R1 may include a memory cell region. The second region R2 may include a peripheral circuit region. The first region R1 may refer to the same region as the memory cell illustrated in FIG. 2. The conductive structures formed in the first region R1 may refer to the same conductive structures as those illustrated in FIG. 2.

An isolation layer 102 and an active region 103 may be formed in the first region R1 and the second region R2 of the substrate 101. A plurality of active regions 103 may be defined by the isolation layer 102. Each active region 103 may have a bar shape having a major axis and a minor axis. The active regions 103 may be arranged to be spaced apart from each other at regular intervals. The active regions 103 may be spaced apart from each other in the first direction D1 and the second direction D2 which is perpendicular to the first direction D1. The active regions 103 may be tilted diagonally.

The substrate 101 may include a material containing silicon. The substrate 101 may include silicon, single crystalline silicon, polysilicon, amorphous silicon, silicon germanium, single crystalline silicon germanium, polycrystalline silicon germanium, carbon-doped silicon, a combination thereof, or a multi-layer thereof. The substrate 101 may also include other semiconductor materials such as germanium. The substrate 101 may include a group-III/V semiconductor substrate, for example, a compound semiconductor substrate, such as GaAs. The substrate 101 may include a silicon-on-insulator (SOI) substrate.

A line-shaped buried gate 106 extending in the first direction D1 may be formed in the first region R1 of the substrate 101. The buried gate 106 may be disposed at a lower level than the top surface of the substrate 101. The buried gate 106 may gap-fill a portion of the gate trench 104. The buried gate 106 may form a buried gate structure along with a gate dielectric layer 105 interposed between the gate trench 104 and the buried gate 106, and a gate capping layer 107 that fills the remaining portion of the gate trench 104 over the buried gate 106. The buried gate structure may be referred to as a ‘buried word line’.

To be specific, the line-shaped gate trench 104 may be formed in the substrate 101 to intersect with the active regions 103 and the isolation layer 102 in the first direction D1. The gate trench 104 may be formed to a predetermined depth in the substrate 101. The bottom surface of the gate trench 104 may be disposed at a higher level than the bottom surface of the isolation layer 102. The gate trench 104 may have a shallower depth than the isolation layer 102. According to another embodiment of the present invention, the isolation layer 102 in the direction that the gate trench 104 extends may be etched to a predetermined depth to form a fin in the active region 103.

The gate dielectric layer 105 may be formed on the surface of the gate trench 104. The buried gate 106 may be formed over the gate dielectric layer 105 to partially fill the gate trench 104. The buried gate 106 may be referred to as a ‘buried conductive layer 106’. The buried gate 106 may be referred to as a ‘buried gate electrode 106’. A gate capping layer (i.e., a sealing layer) 107 may be formed over the buried gate 106 to fill the remaining portion of the gate trench 104. The top surface of the gate capping layer 107 may be disposed at a higher level than the top surface of the substrate 101. The gate capping layer 107 may cover the upper portion of the buried gate 106 and the upper portion of the substrate 101. The buried gate 106 may include a low-resistance metal material. For example, the buried gate 106 may be formed by sequentially stacking titanium nitride and tungsten. According to another embodiment of the present invention, the buried gate 106 may be formed of titanium nitride (TiN) only.

First and second impurity regions 108 and 109 may be formed in the substrate 101. The first and second impurity regions 108 and 109 may be referred to as ‘first and second doped regions 108 and 109’. The first and second impurity regions 108 and 109 may be referred to as ‘first and second source/drain regions 108 and 109’. The first and second impurity regions 108 and 109 may be spaced apart from each other by the gate trench 104. As a result, the buried gate 106 and the first and second impurity regions 108 and 109 may become a cell transistor. The short channel effect may be advantageously improved by forming a cell transistor to have a buried gate structure.

A contact 111 may be formed over the first region R1 of the substrate 101. The contact 111 may be coupled to the first impurity region 108. The contact 111 may protrude toward the upper portion of the gate capping layer 107. The top surface of the contact 111 may be disposed at a higher level than the top surface of the gate capping layer 107. The top surface of the contact 111 may be disposed at a higher level than the surface of the substrate 101. The bottom surface of the contact 111 may be disposed at a lower level than the top surface of the substrate 101. The bottom surface of the contact 111 may be lower than the top surface of the active region 103 including the first and second impurity regions 108 and 109. The contact 111 may have a line width which is smaller than the diameter of the contact hole. A contact spacer 110 may be disposed between the contact 111 and the contact hole. The contact spacer 110 may include a dielectric material. For example, the contact spacer 110 may include silicon nitride. The contact 111 may include a conductive material. For example, the contact 111 may include polysilicon. Also, the contact 111 may include doped polysilicon. In particular, according to this embodiment of the present invention, the contact 111 may include polysilicon that is doped with phosphorus (P). According to another embodiment of the present invention, the contact 111 may include a conductive material. The contact 111 may be referred to as a ‘bit line contact 111’.

A conductive structure 120 may be formed over the contact 111 in the first region R1. The conductive structure 120 may be referred to as a ‘bit line structure 120’. The conductive structure 120 may include a stacked structure of a first barrier layer 112, a second barrier layer 113, a conductive line 114, and a conductive line hard mask 115. The conductive line 114 may be referred to as a ‘bit line 114’. According to another embodiment of the present invention, the stacked structure of the first and second barrier layers 112 and 113 and the conductive line 114 may be referred to as ‘bit lines 112, 113, and 114.’ The conductive line hard mask 115 may be referred to as a ‘bit line hard mask 115’.

The conductive structure 120 may be of a line type extending in the second direction D2. The first and second barrier layers 112 and 113, the conductive line 114, and the conductive line hard mask 115 may be of a line type extending in the second direction D2. The side surfaces of the first and second barrier layers 112 and 113, the conductive line 114, and the conductive line hard mask 115 may be aligned in a direction perpendicular to the surface of the substrate 101. A plurality of conductive structures 120 may be arranged spaced apart from each other in the first direction D1.

A portion of the conductive structure 120 may be coupled to the contact 111. In particular, according to this embodiment of the present invention, the first barrier layer 112 may cover a portion of the contact 111. The first barrier layer 112 may cover the protrusion portion of the contact 111. To be specific, the first barrier layer 112 may cover the top and side surfaces of the protrusion portion of the contact 111 disposed at a higher level than the top surface of the gate capping layer 107. The side surface of the contact 111 disposed at a lower level than the top surface of the gate capping layer 107 may be covered by the contact spacer 110. The first barrier layer 112 may be formed over the contact spacer 110. Accordingly, the side surface of the contact 111 may be covered by a stacked structure of the contact spacer 110 and the first barrier layer 112.

The first barrier layer 112 may include a material having an etch selectivity with respect to the contact 111 and the gate capping layer 107. The first barrier layer 112 may include a conductive material. For example, the first barrier layer 112 may include a stacked structure of titanium (Ti) and tungsten nitride (WN), but the embodiment is not limited thereto.

The second barrier layer 113 may be formed over the first barrier layer 112. The second barrier layer 113 may include a conductive material. For example, the second barrier layer 113 may include tungsten silicide nitride (WSiN), but the embodiment is not limited thereto.

The conductive line 114 may include a metal material. For example, the conductive line 112 may include tungsten (W), but the embodiment is not limited thereto.

The conductive line hard mask 115 may include a dielectric material. For example, the conductive line hard mask 115 may include silicon nitride, but the embodiment is not limited thereto.

A peripheral gate structure may be formed over the substrate 101 in the second region R2. The peripheral gate structure may include a stacked structure of a peripheral gate dielectric layer 201, a high dielectric layer 202, a first peripheral gate electrode 203, a first barrier 112, a second barrier 113, a second peripheral gate electrode 114, and a peripheral gate hard mask 115. The first barrier 112, the second barrier 113, the second peripheral gate electrode 114, and the peripheral gate hard mask 115 may have the same structure as that of the conductive structure 120 of the first region R1.

The first peripheral gate electrode 203 may include a conductive material. For example, the first peripheral gate electrode 203 may include doped polysilicon. In another embodiment, a middle bandgap material layer may be further included between the high dielectric layer 202 and the first peripheral gate electrode 203.

As described above, according to this embodiment of the present invention, as the top surface of the contact 111 applies a protrusion portion disposed at a higher level than the top surface of the gate capping layer 107 and the protrusion portion of the contact 111 is covered by the first barrier layer 112, the contact area between the contact 111 and the conductive structure 120 may be increased. Also, as the contact area is increased, the contact resistance between the contact 111 and the conductive structure 120 may be decreased.

Also, the first barrier layer 112 covers the protrusion of the contact 111, thereby preventing a profile change due to a difference in the etch ratio between the contact 111 and the first barrier layer 112. As a comparative example, when the general contact process and the conductive structure process are sequentially performed, a polysilicon layer is additionally applied as a loss compensation layer between the first barrier layer 112 and the contact 111. However, the present embodiment can prevent profile changes without further deposition of the polysilicon layer.

Also, even though misalignment may occur between the contact 111 and the conductive structure 120, loss of the contact 111 may be minimized based on the etch selectivity between the first barrier layer 112, which is the lowermost layer of the conductive structure 120, and the contact 111. Therefore, there is an effect of stabilizing the formation of spacers of the conductive structure 120 that is formed by a subsequent process. Also, as the formation of spacers is stabilized, there is an effect of preventing a short circuit between the contact 111 and the upper layer.

FIGS. 6A to 60 are cross-sectional views illustrating a method for fabricating a semiconductor device in accordance with another embodiment of the present invention. FIGS. 6A to 60 illustrate a method for fabricating the semiconductor device illustrated in FIG. 5.

The semiconductor device may include a first region R1 and a second region R2, as referenced in FIG. 5. The first region R1 may include a memory cell region. The second region R2 may include a peripheral circuit region. In each of the following drawings, A-A′ cross-sectional view refers to the first region R1, and I-I′ cross-sectional view refers to the second region R2.

Referring to FIG. 6A, an isolation layer 12 may be formed over the substrate 11 and define active regions 13. Referring to FIG. 4, each active region 13 may have a long bar shape having a major axis and a minor axis. The active region 13 may have different shapes in the memory cell region and the peripheral circuit region.

The isolation layer 12 may be formed by a Shallow Trench Isolation (STI) process. The STI process may be performed as follows. The substrate 11 may be etched to form an isolation trench (whose reference numeral is omitted) and the isolation trench may then be filled with a dielectric material to form the isolation layer 12. The isolation layer 12 may include silicon oxide, silicon nitride, or a combination thereof. A Chemical Vapor Deposition (CVD) process or another deposition process may be used to fill the isolation trench with a dielectric material. A planarization process such as Chemical Mechanical Polishing (CMP) may be additionally used.

Subsequently, a buried gate may be formed in the memory cell region.

First, a gate trench 14 may be formed in the substrate 11 of the memory cell region. The gate trench 14 may have a shape of a line crossing the isolation layer 12 and the active region 13. The bottom surface of the gate trench 14 may have a curvature. The bottom surface of the gate trench 14 may be disposed at a higher level than the bottom surface of the isolation layer 12. According to another embodiment of the present invention, the gate trench 14 may include a fin in which a bottom surface of the gate trench 14 in the isolation layer 12 is disposed at a lower level than the bottom surface of the gate trench 14 in the active region 11.

Subsequently, a gate dielectric layer 15 that conformally covers the surface of the gate trench 14 may be formed. The gate dielectric layer 15 may include a dielectric material. For example, the gate dielectric layer 15 may include silicon oxide. The gate dielectric layer 15 may be formed through a deposition process or a selective oxidation process, but the embodiment is not limited thereto.

Subsequently, a buried gate 16 may be formed over the gate dielectric layer 15. Referring to FIG. 4, the buried gate 106 may have a line shape extending in the first direction D1. The buried gate 16 may gap-fill a portion of the gate trench 14. The top surface of the buried gate 16 may be disposed at a lower level than the bottom surfaces of the first and second impurity regions 18 and 19. A channel may be formed along the surface of the gate trench 14 which is gap-filled with the buried gate 16. The buried gate 16 may include a conductive material. The buried gate 16 may include a low-resistance material. The buried gate 16 may include a single structure. According to another embodiment of the present invention, the buried gate 16 may include a stacked structure. For example, the buried gate 16 may include a single structure of tungsten or titanium nitride. According to another embodiment of the present invention, the buried gate 16 may include a stacked structure of titanium nitride and tungsten. According to another embodiment of the present invention, the buried gate 16 may include a stacked structure of tungsten nitride and tungsten. According to another embodiment of the present invention, the buried gate 16 may include a stacked structure of a lower electrode and an upper electrode, and a high work function material may be interposed between the lower electrode and the gate dielectric layer 15, and a low work function material may be interposed between the upper electrode and the gate dielectric layer 15. This embodiment of the present invention is not limited to this, and all known buried gate structures may be applied.

During the buried gate formation process, the peripheral circuit area (I-I′) may be covered with a mask pattern. The mask pattern covering the peripheral circuit region may be removed after forming the buried gate 16 and before forming the gate capping layer 17.

Subsequently, a gate capping layer 17 may be formed over the buried gate 16 to gap-fill the remaining portion of the trench 14. The gate capping layer 17 may be formed by a series of processes of depositing a dielectric material to gap-fill the remaining portion of the trench 14 over the buried gate 16 and performing a planarization process. For example, the planarization process may include a chemical mechanical polishing (CMP) process.

The gate capping layer 17 may cover a top surface of the buried gate 16 and a top surface of the substrate 11 of the memory cell region and the peripheral circuit region. The top surface of the gate capping layer 17 may be disposed at a higher level than the top surface of the substrate 11. The gate capping layer 17 may include a dielectric material. For example, the gate capping layer 17 may include silicon nitride. According to another embodiment of the present invention, the gate capping layer 17 may include a stacked structure. Herein, the stacked structure may include the gate capping layer 17 gap-filling the gate trench 14 and the gate capping layer 17 formed over the substrate 11. Herein, the gate capping layer 17 gap-filling the gate trench 14 and the gate capping layer 17 formed over the substrate 11 may include different dielectric materials.

Subsequently, a first impurity region 18 and a second impurity region 19 may be formed over the substrate 11 of the memory cell region. The first and second impurity regions 18 and 19 may be formed through a doping process such as an implantation process. Hereinafter, the first and second impurity regions 18 and 19 will be referred to as ‘first and second source/drain regions 18 and 19’. The first source/drain region 18 and the second source/drain region 19 may have the same depth. According to another embodiment of the present invention, the first source/drain region 18 may be deeper than the second source/drain region 19. The first source/drain region 18 may be a region to which a bit line contact is to be coupled. The second source/drain region 19 may be a region to which a storage contact is to be coupled.

During the doping process to form the first and second source/drain regions 18 and 19, the substrate 11 of the peripheral circuit region may be covered with a mask pattern. The mask pattern may be removed through a mask pattern removal process after the doping process is completed, and thus the substrate 11 of the peripheral circuit region may be exposed.

Subsequently, a sacrificial layer 20 may be formed over the gate capping layer 17. The sacrificial layer 20 may be applied to form a protrusion portion of the contact through a subsequent process. The sacrificial layer 20 may include a dielectric material having an etch selectivity with respect to the gate capping layer 17. For example, the sacrificial layer 20 may include silicon oxide.

Referring to FIG. 6B, a hard mask pattern 21 and a mask pattern 22 may be formed over the sacrificial layer 20.

The hard mask pattern 21 may include a material having an etch selectivity with respect to the gate capping layer 17 and the substrate 11. The hard mask layer 21 may include a stacked structure. Also, the hard mask layer 21 may include a stacked structure of a carbon-based material and an oxide material. For example, the hard mask layer 21 may include a stacked structure of a first Spin-On-Carbon (SOC) and a first silicon oxynitride (SiON).

Subsequently, a mask pattern 22 may be formed over the hard mask pattern 21. The mask pattern 22 may include a stacked structure of a carbon-based material, an anti-reflection layer, and a photosensitive layer. For example, the mask pattern 22 may include a stacked structure of a second spin-on-carbon, a second silicon oxynitride, and a photoresist.

To form the hard mask pattern 21 and the mask pattern 22, first, a first spin-on-carbon and a first silicon oxynitride for a hard mask may be sequentially formed over the sacrificial layer 20, and a second spin-on-carbon and a second silicon oxynitride for etching the hard mask may be sequentially formed over the first silicon oxynitride. Subsequently, after the upper portion of the second silicon oxynitride is coated with the photosensitive layer, a photoresist pattern may be formed by patterning the photosensitive layer through exposure and development processes, and the mask pattern 22 may be formed by sequentially etching the second silicon oxynitride and the second spin-on-carbon with the photoresist pattern. Subsequently, the hard mask pattern 21 may be formed by sequentially etching the first silicon oxynitride and the first spin-on-carbon by using the mask pattern 22.

Subsequently, a contact hole 23 may be formed by sequentially etching the sacrificial layer 20 and the gate capping layer 17 that are exposed by the hard mask pattern 21. The bottom surface of the contact hole 23 may be disposed at a lower level than the top surface of the substrate 11. The top surface of the first source/drain region 18 may be disposed at a lower level than the top surface of the second source/drain region 19. The side surface of the contact hole 23 may have a positive slope. Accordingly, the line width of the upper portion of the contact hole may be wider than the line width of the lower portion of the contact hole. According to another embodiment of the present invention, the side surface of the contact hole 23 may be vertical.

Subsequently, the hard mask pattern 21 and the mask pattern 22 may be removed. According to another embodiment of the present invention, after the hard mask pattern 21 is formed, the mask pattern 22 may be removed, and the sacrificial layer 20 and the gate capping layer 17 may be patterned by using the hard mask pattern 21, and then the hard mask pattern 21 may also be removed.

Referring to FIG. 6C, a contact spacer 24 covering the inner surface of the contact hole 23 may be formed. The contact spacer 24 may be formed by conformally depositing a dielectric material on the profile of the structure including the contact hole 23, and then performing a spacer etching process on the dielectric material so that the dielectric material remains only on the side surface of the contact hole 23. For example, the spacer etching process may include an etch-back process.

The contact spacer 24 may include a dielectric material. For example, the contact spacer 24 may include silicon nitride. The contact spacer 24 may completely cover the inner side surface of the contact hole 23. The contact hole 23 and the contact spacer 24 may expose the substrate 11, more specifically, the first source/drain region 18.

Referring to FIG. 6D, a contact 25 may be formed to gap-fill the contact hole 23. The contact 25 may be formed by a series of processes of depositing a conductive material that gap-fills the contact hole 23 and then etching the conductive material targeting to expose the top surface of the sacrificial layer 20. For example, the etching of the conductive material may include an etch-back process or a chemical mechanical polishing (CMP) process. For example, the conductive material may include polysilicon. The top surface of the contact 25 may be disposed at the same level as the top surface of the sacrificial layer 20.

Referring to FIG. 6E, a first contact ion implantation process 50 may be performed for reducing the contact resistance by doping the contact 25 with an impurity. For example, the impurity may include phosphorus (P).

Referring to FIG. 6F, the sacrificial layer 20 (see FIG. 6E) may be removed, for example, by an oxide stripping process. The oxide stripping process may include a dry stripping process or a wet stripping process. For example, the dry stripping process can be performed using carbon tetrafluoride (CF₄) and oxygen (O₂). For example, the wet stripping process can be performed using hydrogen fluoride (HF) or buffered oxide etch (BOE). The gate capping layer 17, the contact spacer 24, and the contact 25 may remain without being lost due to their etch selectivity.

Accordingly, the contact 25 and the contact spacer 24 may protrude toward the upper portion of the gate capping layer 17. The top surface of the contact 25 may be disposed at a higher level than the top surface of the gate capping layer 17. The portion of the contact 25 that is at a level higher than the top surface of the gate capping layer 17 may be referred to as a ‘contact protrusion portion’.

Referring to FIG. 6G, a capping oxide layer 26 covering the top surface of the contact 25 may be formed. The capping oxide layer 26 may be formed by an oxidation process. For example, the oxidation process may be performed as a Rapid Thermal Oxidation (RTO) process. The capping oxide layer 26 may cover the entire surface exposed in FIG. 6F, that is, the top surface of the contact 25, a portion of the contact spacer 24, and the top surface of the gate capping layer 17. To be specific, the top surface of the gate capping layer 17, a portion of the contact spacer 24 and the top surface of the contact 25 disposed at a higher level than the gate capping layer 17 and protruding may be replaced with the capping oxide layer 26 through an oxidation process.

In another embodiment, the capping oxide layer 26 may be formed by a deposition process. In this case, the capping oxide layer 26 may be deposited over the top surface of the contact 25, a portion of the contact spacer 24, and the top surface of the gate capping layer 17.

Referring to FIG. 6H, a peri-open mask PO may be formed over the capping oxide layer 26 disposed over the substrate 11 of the memory cell region. The memory cell region may be covered by the peri-open mask PO, however, the peripheral circuit region may be exposed.

Subsequently, the capping oxide layer 26 and the gate capping layer 17 disposed over the substrate 11 of the peripheral circuit region may be removed. Accordingly, the substrate 11 of the peripheral circuit region may be exposed.

Subsequently, the process of forming well and channel in the substrate 11 of the peripheral circuit region may be sequentially performed.

Referring to FIG. 6I, the peri-open mask PO (see FIG. 6H) may be removed.

Referring to FIG. 6J, an insulating material layer 41A may be formed over the substrate 11 of the peripheral circuit region. The insulating material layer 41A is used to form a peripheral gate insulating layer by a subsequent process, and may be formed by an oxidation process or deposition process.

Subsequently, a high dielectric layer 42A and a gate poly layer 43A may be formed sequentially over the capping oxide layer 26 in the memory cell region and the insulating material layer 41A in the peripheral circuit region. The high dielectric layer 42A and the gate poly layer 43A may be configured to form a peripheral gate structure by a subsequent process.

In another embodiment, a middle bandgap material layer may be formed between the high dielectric layer 42A and the gate poly layer 43A.

Referring to FIG. 6K, a cell open mask CO may be formed over the gate poly layer 43A in the peripheral circuit region. The peripheral circuit region may be covered by the cell open mask CO, and the memory cell region may be exposed.

Subsequently, the gate poly layer 43A in the memory cell region may be removed. The high dielectric layer 42A may remain without being removed depending on the etch selectivity.

Referring to FIG. 6L, a second contact ion implantation 60 in the memory cell region may be performed. The second contact ion implantation 60 may be performed at a higher energy level than that of the first contact ion implantation 50. The second contact ion implantation 60 may be adjusted to a higher energy level than the energy level of the first contact ion implantation 50 in consideration of the thicknesses of the capping oxide layer 26 and the high dielectric layer 42A.

The second contact ion implantation 60 may be performed to reduce the contact resistance by doping the contact 25 with an impurity. For example, the impurity may include phosphorus (P).

It is possible to prevent out diffusion of the impurity during a subsequent heat treatment (for example, a heat treatment for activation of an impurity after the gate electrode of the peripheral circuit region is doped with the impurity) by covering the upper portion of the contact 25 with the capping oxide layer 26 during the second contact ion implantation 60. Since the contact 25 includes a high concentration of the impurity, the contact resistance may be reduced.

As a comparative example, when the second contact ion implantation 60 is performed without the capping oxide layer 26, the resistance of the contact 25 may be slightly reduced or may not be reduced at all due to the external diffusion of the impurity during the subsequent heat treatment.

Referring to FIG. 6M, the high dielectric layer 42A (see FIG. 6L) and the capping oxide layer 26 (see FIG. 6L) may be removed. The high dielectric layer 42A and the capping oxide layer 26 may be removed by a cleaning process. The cleaning process may include an oxide stripping process. The oxide stripping process may include a dry stripping process or a wet stripping process. For example, the dry stripping process can be performed using carbon tetrafluoride (CF₄) and oxygen (O₂). For example, the wet stripping process can be performed using hydrogen fluoride (HF) or buffered oxide etch (BOE). As a result, a portion of the contact 25 may protrude toward the upper portion of the gate capping layer 17. The gate capping layer 17 may expose a contact protrusion portion, that is, the top surface of the contact 25 and a portion of the side surface of the contact 25.

As a portion of the protruding capping spacer 24 (see FIG. 6G) is replaced by the capping oxide layer 26, the top surface of the capping spacer 24 may be disposed at the same level as the top surface of the gate capping layer 17.

Subsequently, the cell open mask CO may be removed.

Referring to FIG. 6N, a first barrier layer 28A, a second barrier layer 29A, a conductive material layer 30A, and a conductive line hard mask layer 31A may be sequentially formed over the profile of the structure of the memory cell region and the peripheral circuit region.

The first barrier layer 28A may be conformally lined along the profile of the structure including the contact 25 in the memory cell region and may be formed to cover the gate poly layer 43A in the peripheral circuit region. The first barrier layer 28A may cover the top surface of the contact 25 and a portion of the side surface of the contact 25. The first barrier layer 28A may include a stacked structure. The first barrier layer 28A may include a conductive material. For example, the first barrier layer 28A may include a stacked structure of titanium (Ti) and tungsten nitride (WN).

The second barrier layer 29A may be conformally lined over the first barrier layer 28A. The second barrier layer 29A may include a conductive material. For example, the second barrier layer 29A may include tungsten silicide nitride (WSiN).

The conductive material layer 30A may include a conductive material, such as, for example, tungsten (W). For example, tungsten may be deposited by a physical vapor deposition (PVD) process.

After the conductive material layer 30A is formed, a planarization process may be performed, but the embodiment is not limited to this. For example, the planarization process may include an etch-back process or a Chemical Mechanical Polishing (CMP) process.

The conductive line hard mask layer 31A may protect the conductive material layer 30A and may serve as an etch barrier for etching the conductive material layer 30A, the second barrier layer 29A, and the first barrier layer 28A. The conductive line hard mask layer 31A may include a dielectric material. For example, the conductive line hard mask layer 31A may include silicon nitride.

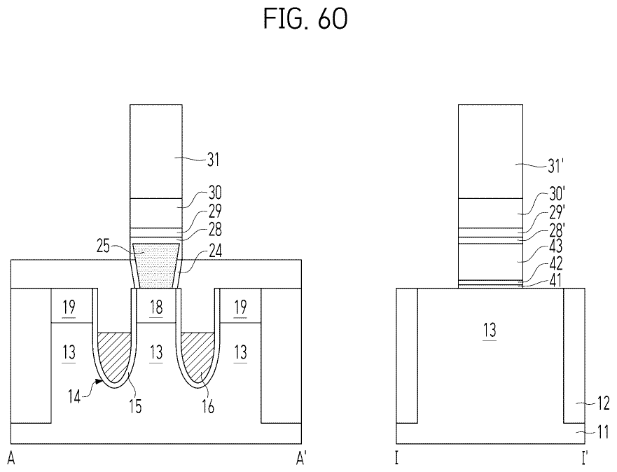

Referring to FIG. 60, a conductive structure may be formed in the memory cell region and the peripheral circuit region, respectively. The conductive structure of the memory cell region may include a stacked structure of a first barrier 28, a second barrier 29, a conductive line 30, and a conductive line hard mask 31.

The conductive structure of the peripheral circuit region may be referred to as ‘peri gate structure’ or ‘peripheral gate structure’ and may include a stacked structure of a peripheral gate dielectric layer 41, a high dielectric layer 42, a first peripheral gate electrode 43, a first peripheral barrier 28′, a second peripheral barrier 29′, a second peripheral gate electrode 30′ and a peripheral gate hard mask 31′.

The first peripheral barrier 28′, the second peripheral barrier 29′, the second peripheral gate electrode 30′ and the peripheral gate hard mask 31′ may each include the same structure as that of the conductive structure in the memory cell region.

According to the embodiment of the present invention, it is possible to prevent contact loss by covering the top surface of the protruding contact of a conductive structure.

According to the embodiment of the present invention, it is possible to prevent outward diffusion of a dopant after contact ion implantation by forming an oxide that covers the top surface of the contact.

According to the embodiment of the present invention, it is possible to prevent an increase in the contact resistance.

According to the embodiment of the present invention, it is possible to prevent a short circuit between a contact and an upper layer.

While the present invention has been described with respect to specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. A semiconductor device comprising:
a gate capping layer formed over a substrate and including a contact hole;
a contact filling the contact hole and including a protrusion portion whose the top surface of the protrusion portion is disposed at a higher level than a top surface of the gate capping layer; and
a first barrier covering top and side surfaces of the contact exposed through an upper portion of the gate capping layer; and
a conductive line over the first barrier.

2. The semiconductor device of claim 1, wherein the contact is directly connected to the substrate.

3. The semiconductor device of claim 1, wherein a bottom surface of the contact hole is disposed at a lower level than a top surface of the substrate.

4. The semiconductor device of claim 1, further comprising:
a contact spacer between the contact and the contact hole.

5. The semiconductor device of claim 4, wherein a top surface of the contact spacer is disposed at the same level as the top surface of the gate capping layer.

6. The semiconductor device of claim 4, wherein the contact spacer includes
a dielectric material having an etch selectivity with respect to the contact.

7. The semiconductor device of claim 4, wherein the contact spacer includes silicon nitride.

8. The semiconductor device of claim 1, wherein the contact overlaps with the first barrier and the conductive line.

9. The semiconductor device of claim 1, wherein the contact includes doped polysilicon.

10. The semiconductor device of claim 1, wherein the contact includes polysilicon that is doped with phosphorus (P).

11. The semiconductor device of claim 1, wherein side surfaces of the first barrier and the conductive line are aligned in a direction perpendicular to a top surface of the substrate.

12. The semiconductor device of claim 1, further comprising:
a second barrier between the first barrier and the conductive line, and
a conductive line hard mask over the conductive line.

13. The semiconductor device of claim 1, wherein the first barrier conformally covers a top surface of the contact and a portion of a side surface of the contact.

14. The semiconductor device of claim 1, wherein the first barrier includes a stacked structure.

15. The semiconductor device of claim 1, wherein the first barrier includes a stacked structure of titanium and tungsten nitride.

16. The semiconductor device of claim 15, wherein titanium of the first barrier reacts with the contact to form titanium silicide.

17. The semiconductor device of claim 1, wherein the conductive line includes a metal material.

18. The semiconductor device of claim 1, wherein the conductive line includes tungsten.

19. The semiconductor device of claim 12, wherein the second barrier includes tungsten silicide nitride.

20. The semiconductor device of claim 12, wherein the conductive line hard mask includes a nitride.

21. The semiconductor device of claim 1, further comprising:
a buried gate formed in the substrate; and
first and second impurity regions formed in the substrate on both sides of the buried gate.

22. A semiconductor device comprising:
a substrate including a first region and a second region;
a gate capping layer formed over the first region of the substrate and including a contact hole;
a contact suitable for gap-filling the contact hole and including a protrusion portion whose top surface is disposed at a higher level than a top surface of the gate capping layer;
a first barrier suitable for covering top and side surfaces of the contact exposed through an upper portion of the gate capping layer;
a conductive line formed over the first barrier to be aligned with a side surface of the first barrier; and
a peripheral gate structure formed over the second region of the substrate.

23. The semiconductor device of claim 22, wherein the contact is directly coupled to the substrate.

24. The semiconductor device of claim 22, wherein a bottom surface of the contact hole is disposed at a lower level than a top surface of the substrate.

25. The semiconductor device of claim 22, further comprising:
a contact spacer between the contact and the contact hole.

26. The semiconductor device of claim 25, wherein a top surface of the contact spacer is disposed at the same level as the top surface of the gate capping layer.

27. The semiconductor device of claim 25, wherein the contact spacer includes
a dielectric material having an etch selectivity with respect to the contact.

28. The semiconductor device of claim 25, wherein the contact spacer includes silicon nitride.

29. The semiconductor device of claim 22, wherein the contact overlaps with the first barrier and the conductive line.

30. The semiconductor device of claim 22, wherein the contact includes doped polysilicon.

31. The semiconductor device of claim 22, wherein the contact includes polysilicon that is doped with phosphorus (P).

32. The semiconductor device of claim 22, further comprising:
a second barrier between the first barrier and the conductive line, and
a conductive line hard mask over the conductive line.

33. The semiconductor device of claim 22, wherein the first barrier conformally covers a top surface of the contact and a portion of a side surface of the contact.

34. The semiconductor device of claim 22, wherein the first barrier includes a stacked structure.

35. The semiconductor device of claim 22, wherein the first barrier includes a stacked structure of titanium and tungsten nitride.

36. The semiconductor device of claim 35, wherein titanium of the first barrier reacts with the contact to form titanium silicide.

37. A method for fabricating a semiconductor device, the method comprising:
forming a gate capping layer and a sacrificial layer including a contact hole over a substrate;
forming a contact spacer that covers an inner surface of the contact hole;
forming a contact to gap-fill the contact hole;
forming a contact protrusion portion whose top surface is disposed at a higher level than a top surface of the gate capping layer by removing the sacrificial layer; and
forming a conductive structure including a first barrier that covers the contact protrusion portion.

38. The method of claim 37, wherein the first barrier conformally covers a top surface of the contact and a portion of a side surface of the contact.

39. The method of claim 37, further comprising:
performing a first contact ion implantation process into the contact, after the forming of the contact.

40. The method of claim 39, wherein the first contact ion implantation process is a process of doping phosphorus (P).

41. The method of claim 37, further comprising:
after forming the contact protrusion portion,
forming a capping oxide layer that conformally covers an entire surface of a structure including the contact protrusion portion; and
performing a second contact ion implantation process onto the contact.

42. The method of claim 41, wherein forming the capping oxide layer includes rapid thermal oxidation (RTO).

43. The method of claim 41, wherein the capping oxide layer is an oxide layer obtained by replacing a top surface of the contact, a portion of the contact spacer, and the top surface of the gate capping layer by an oxidation process.

44. The method of claim 41, wherein the second contact ion implantation process is a process of doping phosphorus.

45. The method of claim 41, further comprising:
performing a heat treatment after the second contact ion implantation process.

46. The method of claim 37, wherein forming the conductive structure includes:
forming a first barrier layer that conformally covers an entire surface of a structure including the contact protrusion portion;
sequentially forming a second barrier layer and a conductive material layer over the first barrier layer;
forming a conductive line hard mask layer over the conductive material layer; and
sequentially etching the conductive line hard mask, the conductive material layer, the second barrier layer, and the first barrier layer.

47. The method of claim 46, wherein the first barrier layer includes a stacked structure of titanium and tungsten nitride.

48. The method of claim 46, wherein the second barrier layer includes tungsten silicide nitride.

49. The method of claim 46, wherein the conductive material layer includes tungsten.

50. The method of claim 37, wherein forming the gate capping layer including the contact hole includes:
forming a gate trench in the substrate;
forming a buried gate to gap-fill a portion of the gate trench;
forming a gate capping layer that gap-fills a remaining portion of the gate trench and covers an upper portion of the substrate over the buried gate; and
forming a contact hole that penetrates the gate capping layer and exposes the substrate.

51. The method of claim 37, wherein forming the contact spacer includes:
forming a dielectric material layer that conformally covers inner and bottom surfaces of the contact hole; and
forming a contact spacer that covers the inner surface of the contact hole by etching the dielectric material layer.

52. A method for fabricating a semiconductor device, comprising:
providing a substrate including a first region and a second region;
forming a gate capping layer including a contact hole over the substrate in the first region;
forming a contact gap-filling the contact hole and including a protrusion portion whose top surface is disposed at a higher level than a top surface of the gate capping layer;
forming a conductive structure over the substrate in the first region, the conductive structure including a first barrier and a conductive line over the first barrier, the first barrier covering top and side surfaces of the contact exposed through an upper portion of the gate capping layer, and the conductive line aligned with a side of the first barrier;
forming a peripheral gate structure over the substrate in the second region.
